(19) United States
(12) Patent Application Publication
(10) Pub. No.: US 2010/0124244 A1
(43) Pub. Date: May 20, 2010

(54) SEMICONDUCTOR LASER DEVICE

(76) Inventors: Atsushi HIGUCHI, Kyoto (JP); Toru TAKAYAMA, Hyogo (JP); Hiroki NAGAI, Hyogo (JP); Kouji MAKITA, Hyogo (JP)

Correspondence Address: MCDERMOTT WILL & EMERY LLP, 600 13TH STREET, NW, WASHINGTON, DC, 20005-3096, US

(21) Appl. No.: 12/556,986

(22) Filed: Sep. 10, 2009

(30) Foreign Application Priority Data
Nov. 18, 2008 (JP) 2008-294622

(51) Int. Cl. H01S 5/323; H01S 5/30; H01S 5/00

(52) U.S. Cl. 372/45.01

(57) ABSTRACT

A semiconductor laser device includes a semiconductor layer including an active layer. The active layer includes: a gain region; an end face window region formed in a region of the active layer including an end face of the semiconductor layer, and having a larger band gap energy than the gain region; and a transition region formed between the gain region and the end face window region. The band gap energy of the transition region continuously changes from the band gap energy of the gain region to that of the end face window region. The gain region and a portion of the transition region located near the gain region form a current injection portion into which current is injected. The end face window region and a portion of the transition region located near the end face window region form a current non-injection portion into which current is prevented from being injected.

### CROSS-REFERENCE TO RELATED APPLICATION

This application claims priority to Japanese Patent Application No. 2008-294622 filed on Nov. 18, 2008, the disclosure of which including the specification, the drawings, and the claims is hereby incorporated by reference in its entirety.

### BACKGROUND

The present disclosure relates generally to semiconductor laser devices, and more particularly relates to a semiconductor laser device having an end face window structure.

Semiconductor laser devices have been widely used in various applications. For example, an aluminum gallium indium phosphide (AlGaInP) based semiconductor laser device capable of emitting a red laser beam in the 650 nm wavelength band is extensively used as a light source in the field of optical disk systems represented by digital versatile disks (DVDs).

A double heterostructure has been known as a typical structure of a semiconductor laser device, wherein an active layer is sandwiched between a cladding layer of a first conductivity type and a cladding layer of a second conductivity type having a mesa-shaped ridge portion (see, for example, Japanese Unexamined Patent Application Publication No. 2001-196694).

In the field of optical disk systems, a semiconductor laser device needs to produce the highest possible optical power in order to rewrite an optical disk at high speed. For example, in order to rewrite a DVD at a 4-fold speed or higher, a semiconductor laser device is required to produce an optical power as high as 100 mW or more. In order to achieve a semiconductor laser device producing such high power, it is necessary to prevent Catastrophic Optical Damage (COD), a phenomenon in which end faces of a semiconductor laser device are melted and destroyed due to high optical power of the semiconductor laser device itself.

An end face window structure is widely used, wherein in order to prevent COD, parts of a quantum well active layer located in the vicinity of the end faces of a semiconductor laser device are disordered by impurity diffusion to increase the band gap energy (see, for example, Japanese Unexamined Patent Application Publication No. 2005-101440).

Formation of an end face window structure can reduce the absorption of lasers in regions of an active layer located near the end faces, and can prevent heat generation on the end faces. Consequently, also when a semiconductor laser device is operated at high power, COD can be prevented, thereby achieving a semiconductor laser device producing an optical power as high as several hundreds of milliwatts or more.

### SUMMARY

However, the present inventors found that when a semiconductor laser device taking on an end face window structure is operated at a low temperature, its optical power-current characteristics may show non-linearity.

As previously described, in forming an end face window structure, regions of a quantum well active layer located in the vicinity of the end faces of a semiconductor laser device are disordered by diffusing impurities thereinto. This increases the band gap energy in the regions of the quantum well active layer located in the vicinity of the end faces. Meanwhile, a transition region where the band gap energy of the active layer gradually changes is formed at the boundary between an end face window region into which impurities are diffused and a gain region achieving laser oscillation without diffusing impurities thereinto (see, for example, Japanese Unexamined Patent Application Publication No. 2005-101440).

The band gap energy in the transition region gradually increases from the gain region toward the end face window region. This provides a part of the transition region in which the difference Δλ between the wavelength corresponding to the local band gap energy of the transition region and the wavelength corresponding to the band gap energy of the gain region is small. The part of the transition region in which the difference Δλ, is small can act as an absorber for laser oscillation light due to band tail states formed in the vicinity of the band edge of the band gap. In particular, in the transition region, impurity states are formed in many parts of the band gap under the influence of impurity diffusion. This increases the influence of the band tail states formed in the vicinity of the band edge of the band gap.

Operation in a wide temperature range from a low temperature of −20° C. to a high temperature of 85° C. is required of semiconductor laser devices for optical disks. The band gap energy in the transition region is different from that in the gain region. Therefore, a part of the active layer located in the transition region does not contribute to light amplification required for laser oscillation, and thus a part of the active layer in the band tail states acts as an absorber for laser oscillation light. In this case, the influence of the light absorption of the absorber increases with decreasing temperature. For this reason, in low-temperature operation at temperatures of 0° C. or less, the influence of the light absorption in the transition region increases. Therefore, the optical power-current characteristics of the laser device may show non-linearity in a range of optical powers of the order of several milliwatts. The range of optical powers of the order of several milliwatts corresponds to the range of optical powers of the laser light needed to play back information on an optical disk. Thus, in the case where sufficient linearity cannot be ensured in low-power operation, an automatic power control (APC) operation becomes difficult.

An object of the present disclosure is to solve the above-described problems and achieve a semiconductor laser device providing optical power-current characteristics showing excellent linearity also in operation at low temperatures.

In the present disclosure, a semiconductor laser device is configured so that current is injected not only into a gain region but also into a part of a transition region.

More specifically, an example semiconductor laser device includes a semiconductor layer forming a resonator, and including a cladding layer of a first conductivity type, an active layer, and a cladding layer of a second conductivity type having a ridge portion. The cladding layer of the first conductivity type, the active layer, and the cladding layer of the second conductivity type are formed sequentially on a substrate. The active layer includes: a gain region; an end face window region formed in a region of the active layer including an end face of the resonator, and having a larger band gap energy than the gain region; and a transition region formed between the gain region and the end face window region. The band gap energy of the transition region continuously changes from the band gap energy of the gain region to the band gap energy of the end face window region. The gain region and a portion of the transition region located near the gain region form a current injection portion into which current is injected. The end face window region and a portion of the transition region located near the end face window region form a current non-injection portion into which current is prevented from being injected.

### BRIEF DESCRIPTION OF THE DRAWINGS

FIGS. 1A and 1B show an example semiconductor laser device, wherein FIG. 1A is a plan view of the example semiconductor laser device, and FIG. 1B is a cross-sectional view taken along the line Ib-Ib in FIG. 1A.

FIG. 2 is a graph showing the wavelength of the absorption edge of an active layer of the example semiconductor laser device.

FIG. 3A is a graph showing the optical power-current characteristics of the example semiconductor laser device when the local mode loss in a transition region is 0.01 cm⁻¹.

FIG. 3B is a graph showing the optical power-current characteristics of the example semiconductor laser device when the local mode loss in the transition region is 0.03 cm⁻¹.

FIG. 3C is a graph showing the optical power-current characteristics of the example semiconductor laser device when the local mode loss in the transition region is 0.05 cm⁻¹.

FIG. 3D is a graph showing the optical power-current characteristics of the example semiconductor laser device when the local mode loss in the transition region is 0.07 cm⁻¹.

FIG. 3E is a graph showing the optical power-current characteristics of the example semiconductor laser device when the local mode loss in the transition region is 0.1 cm⁻¹.

FIG. 4 is a graph showing, at given operating temperatures of the example semiconductor laser device, the correlation between the wavelength of the absorption edge of a part of an active layer located at the boundary between a current injection portion and a current non-injection portion of the example semiconductor laser device, and the local mode loss in the transition region.

FIGS. 5A and 5B are graphs showing the optical power-current characteristics of the example semiconductor laser device and the optical power-current characteristics of a known semiconductor laser device, respectively.

FIG. 6 is a graph showing, at given carrier concentrations in a ridge portion of a p-type cladding layer, the correlation between the wavelength of the absorption edge of the part of the active layer located at the boundary between the current injection portion and the current non-injection portion of the example semiconductor laser device, and the local mode loss in the transition region.

FIG. 7A is a graph showing the optical power-current characteristics of the example semiconductor laser device when the carrier concentration in the ridge portion is 3×10¹⁷ cm⁻³.

FIG. 7B is a graph showing the optical power-current characteristics of the example semiconductor laser device when the carrier concentration in the ridge portion is 5×10¹⁷ cm⁻³.

FIG. 7C is a graph showing the optical power-current characteristics of the example semiconductor laser device when the carrier concentration in the ridge portion is 1×10¹⁸ cm⁻³.

FIG. 7D is a graph showing the optical power-current characteristics of the example semiconductor laser device when the carrier concentration in the ridge portion is 2×10¹⁸ cm⁻³.

FIG. 7E is a graph showing the optical power-current characteristics of the example semiconductor laser device when the carrier concentration in the ridge portion is 3×10¹⁸ cm⁻³.

FIG. 8 is a graph showing, for given heights of the ridge portion, the correlation between the wavelength of the absorption edge of the part of the active layer located at the boundary between the current injection portion and the current non-injection portion of the example semiconductor laser device, and the local mode loss in the transition region.

FIG. 9 is a graph showing the relationship between the height of the ridge portion of the example semiconductor laser device and the operating voltage thereof

FIG. 10A is a graph showing the optical power-current characteristics of the example semiconductor laser device when the height of the ridge portion 20a is 1.0 μm.

FIG. 10B is a graph showing the optical power-current characteristics of the example semiconductor laser device when the height of the ridge portion 20a is 1.3 μm.

FIG. 10C is a graph showing the optical power-current characteristics of the example semiconductor laser device when the height of the ridge portion 20a is 1.6 μm.

FIG. 10D is a graph showing the optical power-current characteristics of the example semiconductor laser device when the height of the ridge portion 20a is 1.9 μm.

FIG. 10E is a graph showing the optical power-current characteristics of the example semiconductor laser device when the height of the ridge portion 20a is 2.2 μm.

FIG. 11 is a graph showing, for given thicknesses of the p-type cladding layer, the correlation between the wavelength of the absorption edge of the part of the active layer located at the boundary between the current injection portion and the current non-injection portion of the example semiconductor laser device, and the local mode loss in the transition region.

FIG. 12A is a graph showing the optical power-current characteristics of the example semiconductor laser device when the thickness of the p-type cladding layer 16 is 0.05 μm.

FIG. 12B is a graph showing the optical power-current characteristics of the example semiconductor laser device when the thickness of the p-type cladding layer 16 is 0.1 μm.

FIG. 12C is a graph showing the optical power-current characteristics of the example semiconductor laser device when the thickness of the p-type cladding layer 16 is 0.25 μm.

FIG. 12D is a graph showing the optical power-current characteristics of the example semiconductor laser device when the thickness of the p-type cladding layer 16 is 0.4 μm.

FIG. 12E is a graph showing the optical power-current characteristics of the example semiconductor laser device when the thickness of the p-type cladding layer 16 is 0.45 μm.

### DETAILED DESCRIPTION

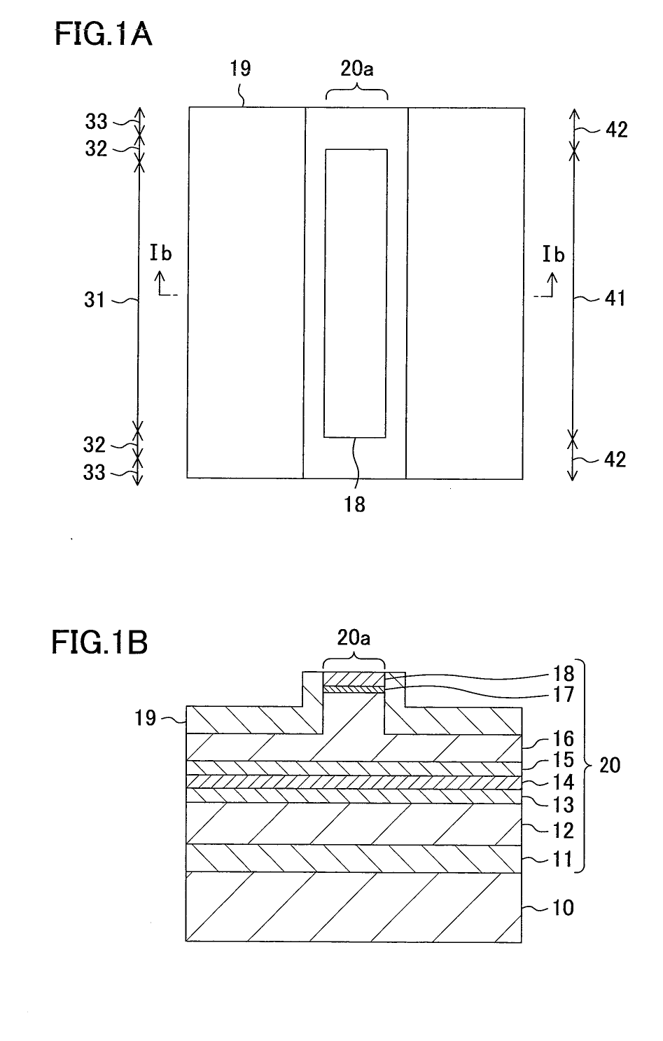

An example embodiment of the present invention will be described with reference to the drawings. FIGS. 1A and 1B show the structure of an example semiconductor laser device, wherein FIG. 1A is a plan view thereof, and FIG. 1B is a cross-sectional view taken along the line Ib-Ib in FIG. 1A. Although in this example embodiment a semiconductor laser device emitting infrared light in the 780 nm wavelength band will be described as a specific example, this is not restrictive. Furthermore, for the sake of simplicity, a p-side electrode and an n-side electrode are omitted.

As shown in FIGS. 1A and 1B, a semiconductor layer 20 forming a resonator is formed on a substrate 10 forming an n-type GaAs substrate. The semiconductor layer 20 includes a buffer layer 11, an n-type cladding layer 12, a first guide layer 13, an active layer 14, a second guide layer 15, a p-type cladding layer 16, a protective layer 17, and a contact layer 18, which are formed sequentially on the substrate 10.

The buffer layer 11 is made of n-type GaAs with a thickness of 0.5 μm, and the n-type cladding layer 12 is made of n-type (Al_{0.7}Ga_{0.3})_{0.51}In_{0.49}P with a thickness of 2.0 μm. The first guide layer 13 is made of Al_{0.5}Ga_{0.5}As, and the active layer 14 is a quantum well active layer obtained by alternately stacking a well layer made of GaAs and a barrier layer made of Al_{0.5}Ga_{0.5}As. The second guide layer 15 is made of Al_{0.5}Ga_{0.5}As, and the p-type cladding layer 16 is made of (Al_{0.7}Ga_{0.3})_{0.51}In_{0.49}P. The p-type cladding layer 16 has a stripe-shaped ridge portion 20a. The upper surface of a portion of the p-type cladding layer 16 other than the ridge portion 20a and the sidewalls of the ridge portion 20a are covered with a 0.3 μm-thick current blocking layer 19 made of silicon nitride (SiN). The protective layer 17 and the contact layer 18 are formed on the ridge portion 20a. The protective layer 17 is made of p-type Ga_{0.51}In_{0.49}P with a thickness of 50 nm, and the contact layer 18 is made of p-type GaAs with a thickness of 0.4 μm.

The distance between the top surface of the ridge portion 20a of the p-type cladding layer 16 and the top surface of the active layer 14 is 1.4 μm. The distance dp between the lower end of the ridge portion 20a of the p-type cladding layer 16 and the top surface of the active layer 14 is 0.24 μm.

The current injected through the contact layer 18 is confined only to the ridge portion 20a by the current blocking layer 19, and is therefore injected intensively to a part of the active layer 14 located under the ridge portion 20a. Therefore, an injected current as low as several tens of milliamperes can provide a population inversion of carriers required for laser oscillation.

Light is emitted by recombination of the carriers injected to the part of the active layer 14. The emitted light is confined vertically to the top and bottom surfaces of the active layer 14 by the p-type cladding layer 16 and the n-type cladding layer 12. The emitted light is confined in the direction parallel to the top and bottom surfaces of the active layer 14 by the current blocking layer 19 having a lower refractive index than the cladding layers.

Since the current blocking layer 19 is transparent to laser oscillation light, there is no light absorption. Therefore, a low loss waveguide can be provided. Moreover, light propagating through the waveguide can exude largely into the current blocking layer 19. A value on the order of 10⁻³ suitable for high power operation can therefore be easily obtained as the effective refractive index difference Δn between the inner and outer sides of the ridge portion 20a. The effective refractive index difference Δn can be precisely controlled on the order of 10⁻³ by changing the distance dp. This can provide a low operating current, high power semiconductor laser that can precisely control light distribution. In this example embodiment, the distance dp is 0.24 μm, and therefore the difference Δn is 4×10⁻³. Thus, a light beam having full-width-at-half-maximum (FWHM) horizontal and vertical divergence angles of 8 and 16.2 degrees, respectively, suitable for a light source for a read/write optical disk can be stably oscillated in the fundamental transverse mode.

One (the front end face) of the faces of the resonator-forming semiconductor layer 20 in a direction crossing the stripe-shaped ridge portion 20a is coated with a dielectric film with 7% reflectivity, and the other one (the rear end face) thereof is coated with a dielectric film with 94% reflectivity. Disordered end face window regions 33 are formed in regions of the active layer 14 located in the vicinity of the end faces of the resonator. The end face window regions 33 of the active layer 14 each have a larger band gap energy than a gain region 31 thereof producing laser oscillation. This reduces the absorption of laser beams. This reduction can reduce heat generation at the end faces of the resonator and prevent the occurrence of COD causing the end faces of a semiconductor laser device to melt and be destroyed.

The end face window regions 33 are formed by diffusing impurities into the active layer 14. Therefore, transition regions 32 in each of which the band gap energy continuously changes are formed between the gain region 31 and the end face window regions 33 by the spread of the diffused impurities.

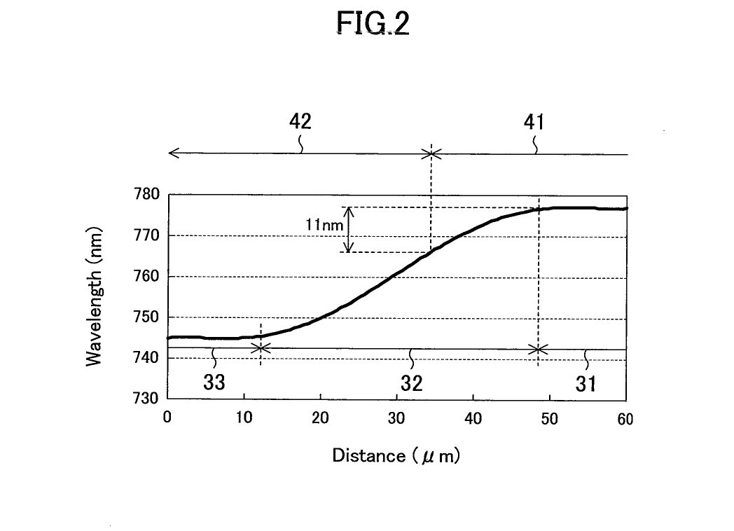

FIG. 2 shows variations in the wavelength of the absorption edge of the active layer 14 of the example semiconductor laser device. In FIG. 2, the distance from an end face of the resonator is shown along the horizontal axis, and the wavelength of the absorption edge of a part of the active layer 14 in each of the regions is shown along the vertical axis. Here, the wavelength of the absorption edge means the wavelength of the minimum-energy-level component of the light absorbed by a semiconductor, which is determined by the band gap energy of the semiconductor. With an increase in the band gap energy, the wavelength of the absorption edge is shortened.

As shown in FIG. 2, the wavelength of the absorption edge of the gain region 31 is approximately 777 nm. The disordering of each end face window region 33 increases the band gap energy thereof, and the wavelength of the absorption edge thereof is therefore approximately 745 nm. The band gap energy of each of the transition regions 32 between the gain region 31 and the end face window regions 33 gradually increases from the gain region 31 toward the associated end face window region 33. Accordingly, the wavelength of the absorption edge of the transition region 32 is continuously shortened from that of the gain region 31, i.e., approximately 777 nm, to that of the end face window region 33, i.e., approximately 745 nm.

For a known semiconductor laser device, no current has been injected into transition regions and end face window regions. In other words, the boundaries between a current injection portion of an active layer into which current is injected and current non-injection portions thereof into which no current is injected coincide with the boundaries between a gain region and the transition regions.

For the example semiconductor laser device, the boundaries between a current injection portion 41 of the active layer 14 into which current is injected and current non-injection portions 42 thereof are located in the transition regions 32. More specifically, each of the boundaries is closer to the associated end face window region 33 than the location at which the wavelength of the absorption edge of the associated transition region 32 is 11 nm shorter than that of the gain region 31. Thus, the local mode loss of the transition region 32 becomes 0.03 cm⁻¹ or less, resulting in optical power-current characteristics providing excellent linearity. The local mode loss of the transition region 32 means the sum of losses obtained by integrating, over the transition region 32, the result obtained by multiplying the local absorption loss of the active layer 14 by the optical confinement factor of the active layer 14.

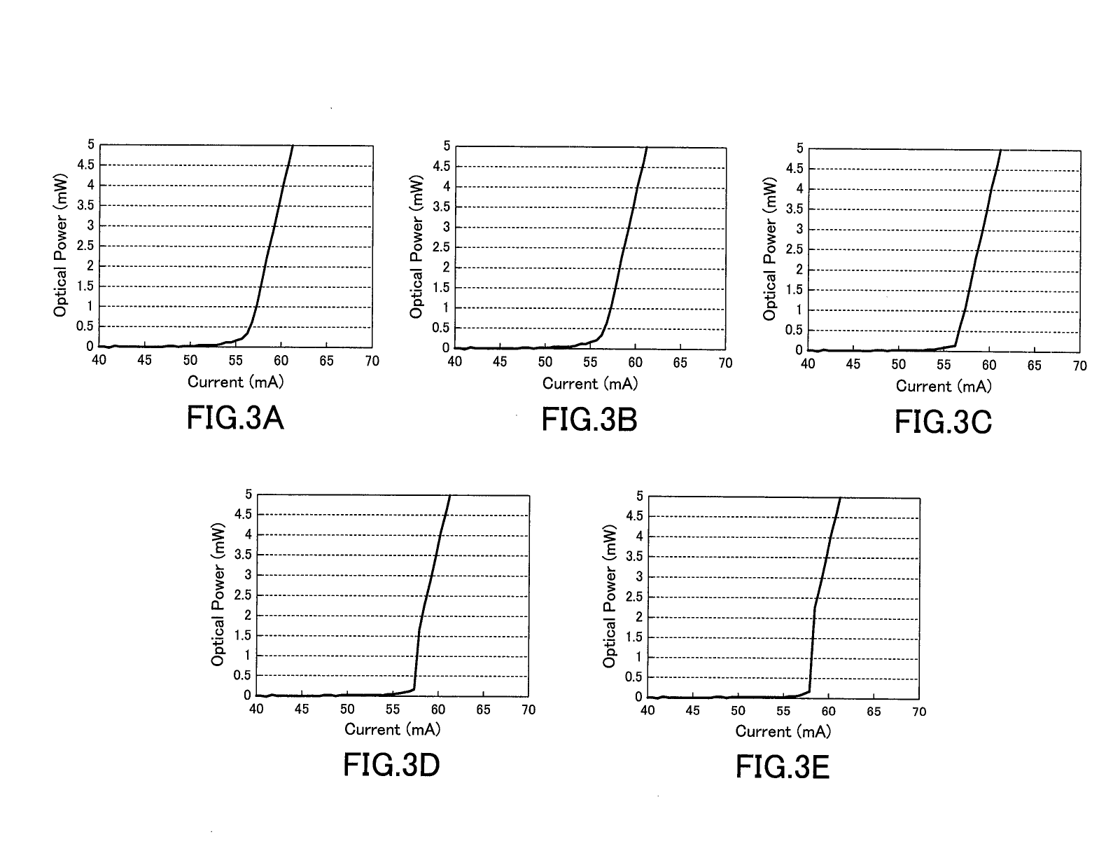

FIG. 3A shows the optical power-current characteristics of the example semiconductor laser device at 0° C. when the local mode loss of each transition region 32 is 0.01 cm⁻¹. FIG. 3B shows the optical power-current characteristics at 0° C. when the local mode loss thereof is 0.03 cm⁻¹. FIG. 3C shows the optical power-current characteristics at 0° C. when the local mode loss thereof is 0.05 cm⁻¹. FIG. 3D shows the optical power-current characteristics at 0° C. when the local mode loss thereof is 0.07 cm⁻¹. FIG. 3E shows the optical power-current characteristics at 0° C. when the local mode loss thereof is 0.1 cm⁻¹. In FIGS. 3A through 3E, the local mode loss of the transition region 32 is changed by changing the locations of the boundaries between the current injection portion 41 and the current non-injection portions 42. The local mode loss in each of FIGS. 3A through 3E is obtained by incorporating variations in the length of each current non-injection portion 42, as a parameter, into the local mode loss of a portion of the transition region 32 corresponding to the current non-injection portion 42.

The band gap energy of each transition region 32 gradually decreases from the associated end face window region 33 toward the gain region 31. For this reason, a part of the transition region 32 in tail states formed in the vicinity of the band edge of the transition region 32 acts as an absorber for laser oscillation light. The absorption coefficient of the absorber increases with decreasing temperature. Therefore, at low temperatures, such as 0° C., the light absorption in the transition region 32 has a more significant influence than at room temperature. However, when, as shown in FIGS. 3A and 3B, the local mode loss of the transition region 32 is 0.03 cm⁻¹ or less, optical power-current characteristics providing excellent linearity can be achieved even at low temperatures, such as 0° C.

The influence exerted on the optical power-current characteristics by the magnitude of the local mode loss of each transition region 32 will be described in detail. A local mode loss induced in the transition region 32 leads to a light absorption loss, resulting in the increased oscillation threshold current and the reduced slope efficiency in the optical power-current characteristics. The reason why the oscillation threshold current increases is that the loss of a waveguide increases due to the local mode loss of the transition region 32, resulting in an increase in the gain required for laser oscillation. Furthermore, the reason why the slope efficiency is reduced is that the optical amplification gain of the active layer per unit injection current is decreased in a waveguide causing high waveguide loss. For this reason, as the local mode loss of the transition region 32 gradually increases, the oscillation threshold current gradually increases, and the slope efficiency is gradually reduced.

With a further increase in the local mode loss of each transition region 32, the amount of laser light absorbed in the transition region 32 also increases. As a result, many electron-hole pairs are generated in absorption states of the transition region 32. This causes absorption saturation, i.e., a phenomenon in which the absorption states are filled with carriers so that the optical absorption is reduced. The absorption saturation reduces the local mode loss, resulting in the reduced waveguide loss and the abruptly increased slope efficiency. Therefore, the optical power-current characteristics show non-linearity. The experiment conducted by the present inventors showed that when the local mode loss of the transition region at 0° C. is greater than 0.03 cm⁻¹, the optical power-current characteristics show non-linearity.

The non-linearity in the optical power-current characteristics is caused in an optical power range of several milliwatts as shown in FIGS. 3C through 3E. The power of laser light in this range corresponds to the power of the laser light used to play back information on an optical disk. Therefore, non-linear optical power-current characteristics make it difficult to allow a semiconductor laser device to implement an automatic power control (APC) operation.

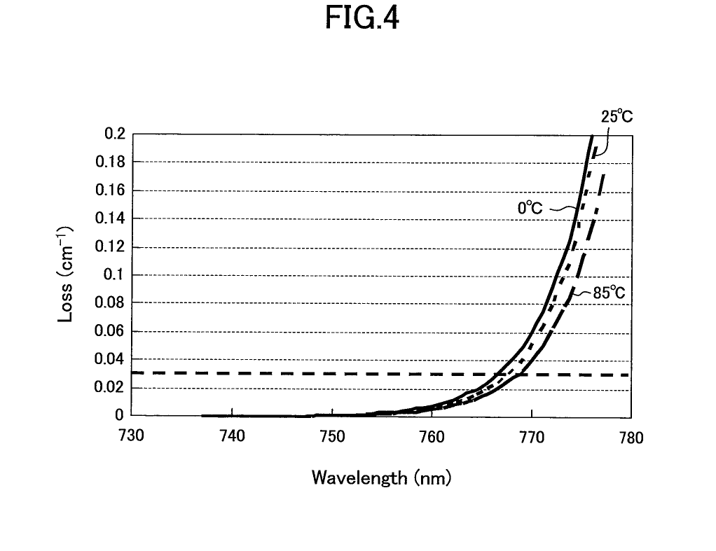

FIG. 4 shows the correlation between the wavelength of the absorption edge of each of parts of the active layer 14 located at the boundaries between the current injection portion 41 and the current non-injection portions 42 and the local mode loss of the associated transition region 32 under temperatures of 0° C., 25° C., and 85° C. In FIG. 4, calculations are performed on the assumption that the gain wavelength of the semiconductor laser device is 777 nm, the carrier concentration in the ridge portion 20a is 1×10¹⁸ cm⁻³, the height of the ridge portion 20a is 1.3 μm, and a part of the p-type cladding layer 16 located under the ridge portion 20 has a thickness of 0.15 μm.

As shown in FIG. 4, the local mode loss at 0° C. is greater than that at 25° C. and that at 85° C. This coincides with a typical property of a semiconductor laser, i.e., the property in which the light absorption in the transition regions 32 increases with decreasing temperature so that the waveguide loss increases.

In this case, at a temperature of 0° C., in order to allow the local mode loss in the transition region 32 to be 0.03 cm⁻¹ or less and ensure the linearity of the optical power-current characteristics, the wavelength of the absorption edge of the active layer 14 at each of the boundaries between the current injection portion 41 and the current non-injection portions 42 needs to be 766 nm or less. In other words, the boundaries between the current injection portion 41 and the current non-injection portions 42 need to be provided in regions of the active layer 14 each having a wavelength that is 11 nm or more different from the gain wavelength, and current needs to be injected into regions of the transition regions 32 each having a wavelength that is 11 nm or less different from the gain wavelength.

When current is injected into regions of the transition regions 32 each having a wavelength that is insignificantly different from the gain wavelength, current is injected into the tail states and the impurity states both formed in the vicinity of the band edge of the band gap, resulting in the tail states filled with carriers. A part of each transition region 32 in the tail states filled with carriers does not act as an absorber, resulting in the reduced local mode loss.

For the example semiconductor laser device, the boundaries between the current injection portion 41 and the current non-injection portions 42 are located in the transition regions 32. More particularly, current is injected into the gain region 31 of the active layer 14 and parts of the transition regions 32 of the active layer 14 located near the gain region 31, and current is not injected into the end face window regions 33 and parts of the transition regions 32 located near the end face window regions 33. Therefore, current is injected into the tail states formed in the vicinity of the band edge of the band gap of each transition region 32. Consequently, the tail states are filled with carriers, and a part of the active layer 14 in the tail states thus does not act as an absorber, resulting in the improved linearity of the optical power-current characteristics, in particular, in low-temperature operation.

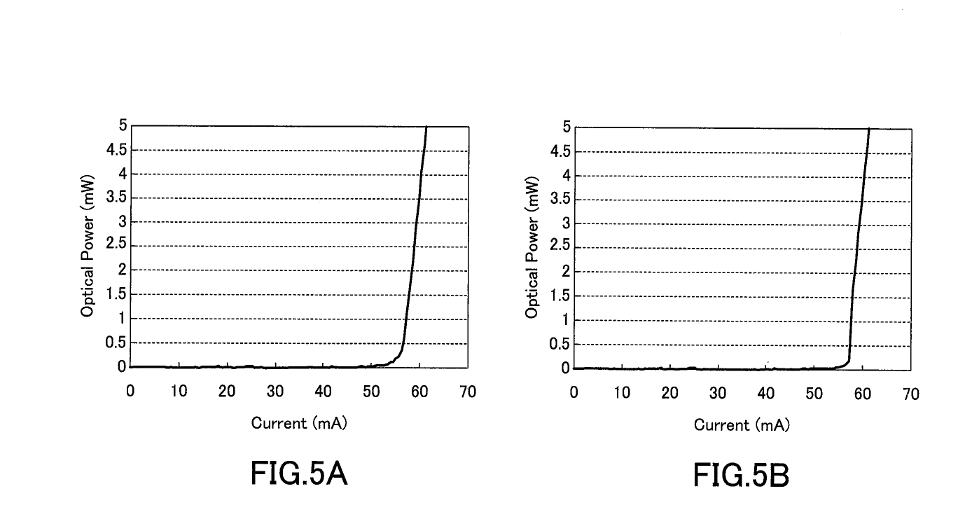

FIGS. 5A and 5B show the optical power-current characteristics of the example semiconductor laser device at 0° C. as compared with those of a known semiconductor laser device. The linearity of the optical power-current characteristics of the example semiconductor laser device shown in FIG. 5A is superior to that of the known semiconductor laser device shown in FIG. 5B.

In order to form the boundaries between the current injection portion 41 and the current non-injection portions 42 in the transition regions 32, for example, the location at which the contact layer 18 is formed needs to be adjusted. More specifically, as shown in FIG. 1A, the contact layer 18 is formed on the ridge portion 20a to cover the gain region 31 and parts of the transition regions 32 located near the gain region 31. Furthermore, the current blocking layer 19 is left on the end face window regions 33 and parts of the transition regions 32 located near the end face window regions 33.

The following description will be given of a result obtained by considering other parameters for improving the linearity of the optical power-current characteristics in low-temperature operation.

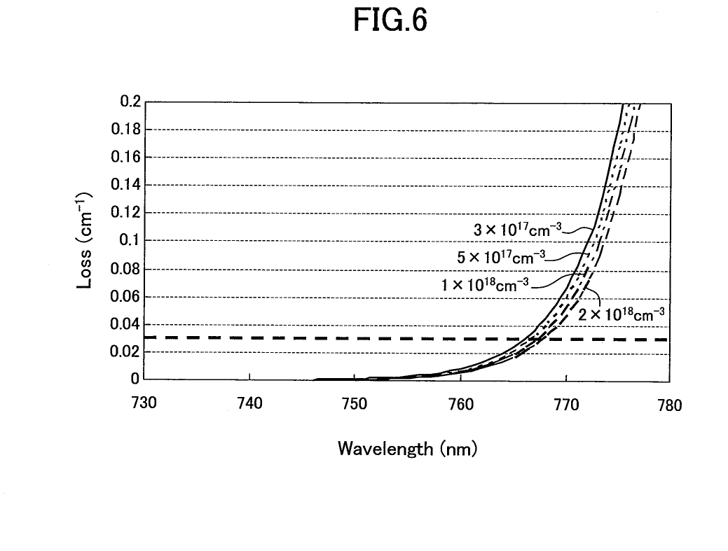

FIG. 6 shows the correlation between the wavelength of the absorption edge of each of parts of the active layer 14 located at the boundaries between the current injection portion 41 and the current non-injection portions 42 and the local mode loss of the associated transition region 32 when the carrier concentration in the ridge portion 20a is changed. In FIG. 6, calculations are performed on the assumption that the gain wavelength of the example semiconductor laser device is 777 nm and the temperature thereof is 0° C.

As shown in FIG. 6, with the increasing carrier concentration in the ridge portion 20a, the local mode loss of each transition region 32 is reduced. Absorption states formed in the vicinity of the band edge of the band gap, i.e., tail states, and impurity states created by the diffusion of impurities from each of the end face window regions 33 are produced in the associated transition region 32. Meanwhile, when the carrier concentration in the ridge portion 20a is increased, the resistance of the ridge portion 20a is reduced, resulting in the increased spread of current toward the end face of the example semiconductor laser device. The spread of current may occur when current injected from the ridge portion 20a flows into the active layer 14. When the spread of current toward the end face is increased, current is injected into the tail states and the impurity states in the transition region 32. Consequently, these states are filled with carriers, and thus light absorption is reduced. Therefore, the local mode loss may be reduced.

Furthermore, when the carrier concentration in the ridge portion 20a is 3×10¹⁸ cm⁻³ or more, p-type impurities in the ridge portion 20a become more likely to thermally diffuse into a region of the active layer 14 except the end face window regions 33. The diffusion of p-type impurities into the gain region 31 allows nonradiative recombination centers to be formed in the gain region 31, resulting in reduced luminous efficiency. In view of the above, the carrier concentration in the ridge portion 20a is preferably 2×10¹⁸ cm⁻³ or less. In this example embodiment, in order to reduce the resistance of the ridge portion 20a while keeping nonradiative recombination centers from being formed in the gain region 31, the carrier concentration should be 1×10¹⁸ cm⁻³.

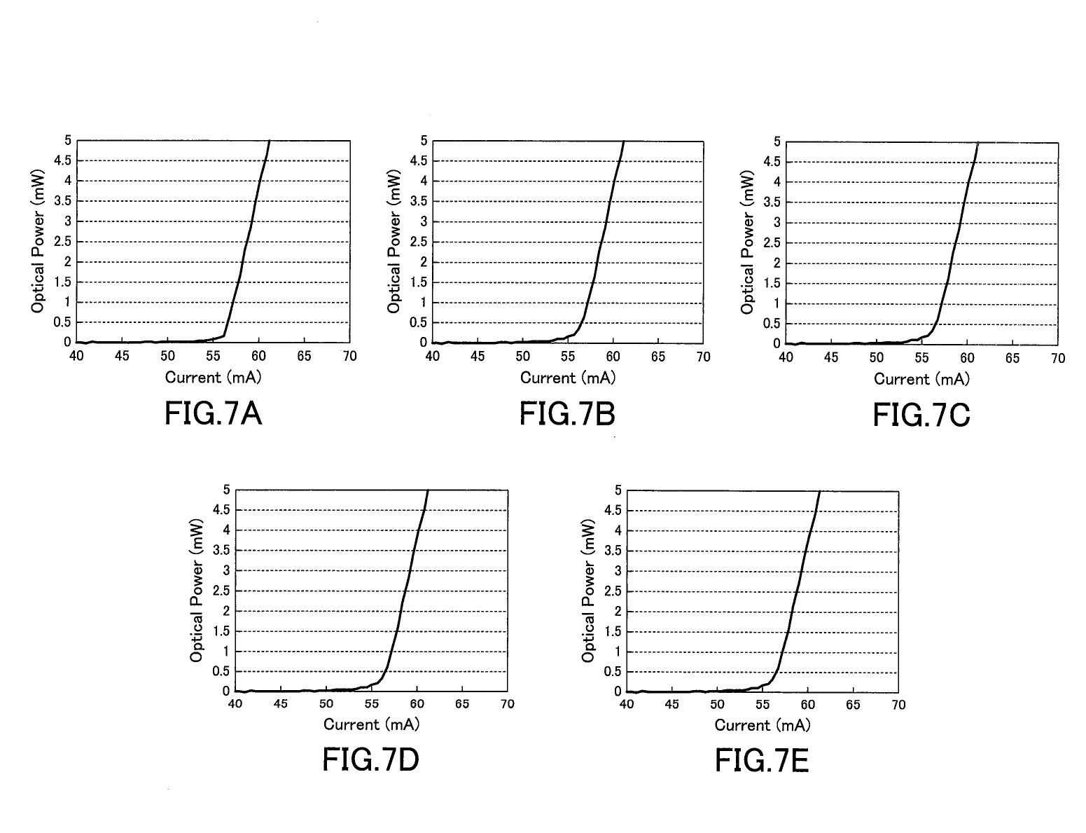

FIG. 7A shows the optical power-current characteristics of the example semiconductor laser device at 0° C. when the carrier concentration in the ridge portion 20a is 3×10¹⁷ cm⁻³. FIG. 7B shows the optical power-current characteristics at 0° C. when the carrier concentration in the ridge portion 20a is 5×10¹⁷ cm⁻³. FIG. 7C shows the optical power-current characteristics at 0° C. when the carrier concentration in the ridge portion 20a is 1×10¹⁸ cm⁻³. FIG. 7D shows the optical power-current characteristics at 0° C. when the carrier concentration in the ridge portion 20a is 2×10¹⁸ cm⁻³. FIG. 7E shows the optical power-current characteristics at 0° C. when the carrier concentration in the ridge portion 20a is 3×10¹⁸ cm⁻³.

As shown in FIG. 7A, when the carrier concentration in the ridge portion 20a is 3×10¹⁷ cm⁻³, the optical power-current characteristics show non-linearity. In contrast to this, as shown in FIGS. 7B through 7E, when the carrier concentration therein is 5×10¹⁷ cm⁻³, 1×10¹⁸ cm⁻³, 2×10¹⁸ cm³, or 3×10¹⁸ cm⁻³, the optical power-current characteristics do not show non-linearity. More particularly, if the carrier concentration in the ridge portion 20a is 5×10¹⁷ cm⁻³ or more, the absorption states in the transition region 32 are filled with carriers, and a part of the active layer 14 in the absorption states thus does not act as an absorber. This can provide optical power-current characteristics showing excellent linearity without showing non-linearity also in low-temperature operation at low temperatures of 0° C. or less.

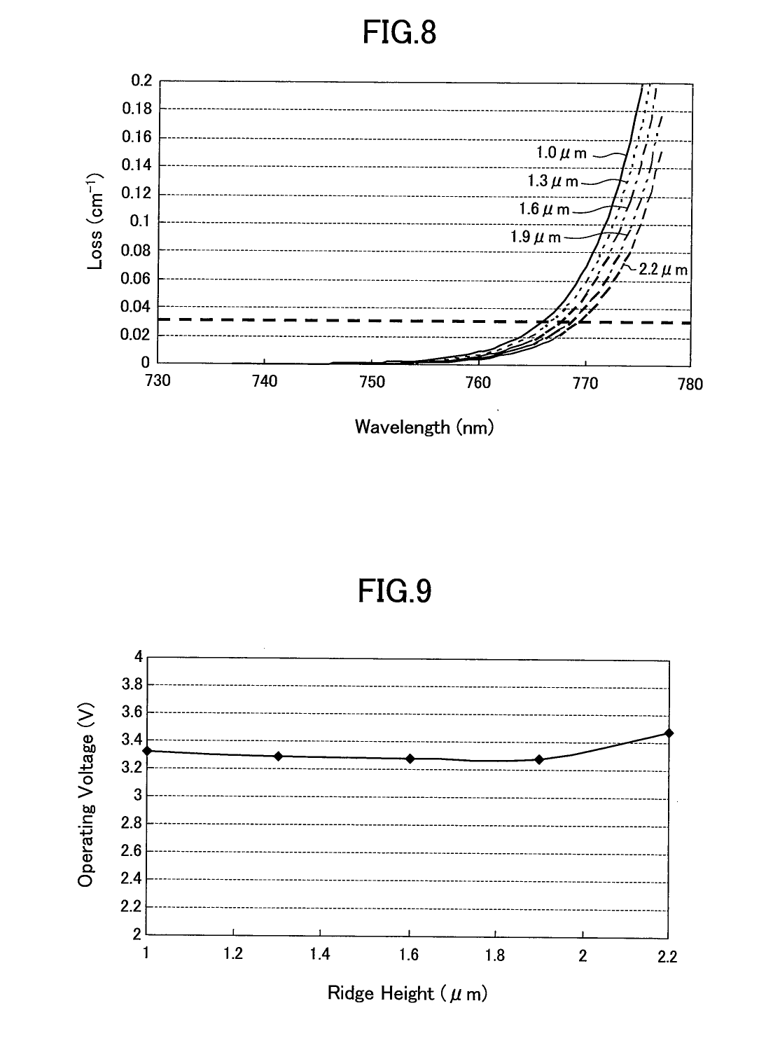

FIG. 8 shows the correlation between the wavelength of the absorption edge of each of parts of the active layer 14 located at the boundaries between the current injection portion 41 and the current non-injection portions 42 and the local mode loss of the associated transition region 32 when the height of the ridge portion 20a is changed. In FIG. 8, calculations are performed on the assumption that the gain wavelength of the example semiconductor laser device is 777 nm and the temperature thereof is 0° C. The height of the ridge portion 20a means the distance from the top surface of the ridge portion 20a to the bottom surface of the current blocking layer 19.

As shown in FIG. 8, with the increasing height of the ridge portion 20a, the local mode loss of the transition region 32 is reduced. When the height of the ridge portion 20a is increased, the spread of current toward the end face of the active layer 14 is increased. The spread of current may occur when current injected from the ridge portion 20a flows into the active layer 14. When the spread of current toward the end face is increased, current is injected into the tail states and the impurity states in the transition region 32. Consequently, these states are filled with carriers, and thus light absorption is reduced. Therefore, the local mode loss may be reduced.

However, when the height of the ridge portion 20a is increased too much, the series resistance of the ridge portion 20a increases, resulting in the increased operating voltage of the example semiconductor laser device. When the operating voltage increases, the following serious problem arises: If the semiconductor laser device is operated at high temperature and high power, a desired optical power level cannot be achieved because the operating voltage approaches the maximum supply voltage (3.5 V) of a laser drive circuit. FIG. 9 shows the relationship between the operating voltage of the example semiconductor laser device and the height of the ridge portion 20a in high-temperature/high-power pulse driving operation at an operating temperature of 85° C., a duty ratio of 40%, and a power of 350 mW. When the height of the ridge portion 20a is 1.0 μm through 1.9 μm, an increase in the height of the ridge portion 20a decreases the operating voltage. However, when the height of the ridge portion 20a is 2.2 μm, the operating voltage increases. The increase in the height of the ridge portion 20a increases the distance between the contact layer 18 formed on the ridge portion 20a and the active layer 14. The increase in the distance between the contact layer 18 and the active layer 14 reduces the light absorption loss produced by the contact layer 18 absorbing the light distribution propagating through the waveguide. This reduction increases the slope efficiency of the laser device. Consequently, the operating current value is reduced, resulting in the reduced operating voltage. However, when the distance between the contact layer 18 and the active layer 14 increases too much, the series resistance itself of the ridge portion 20a increases. Therefore, the operating voltage may increase.

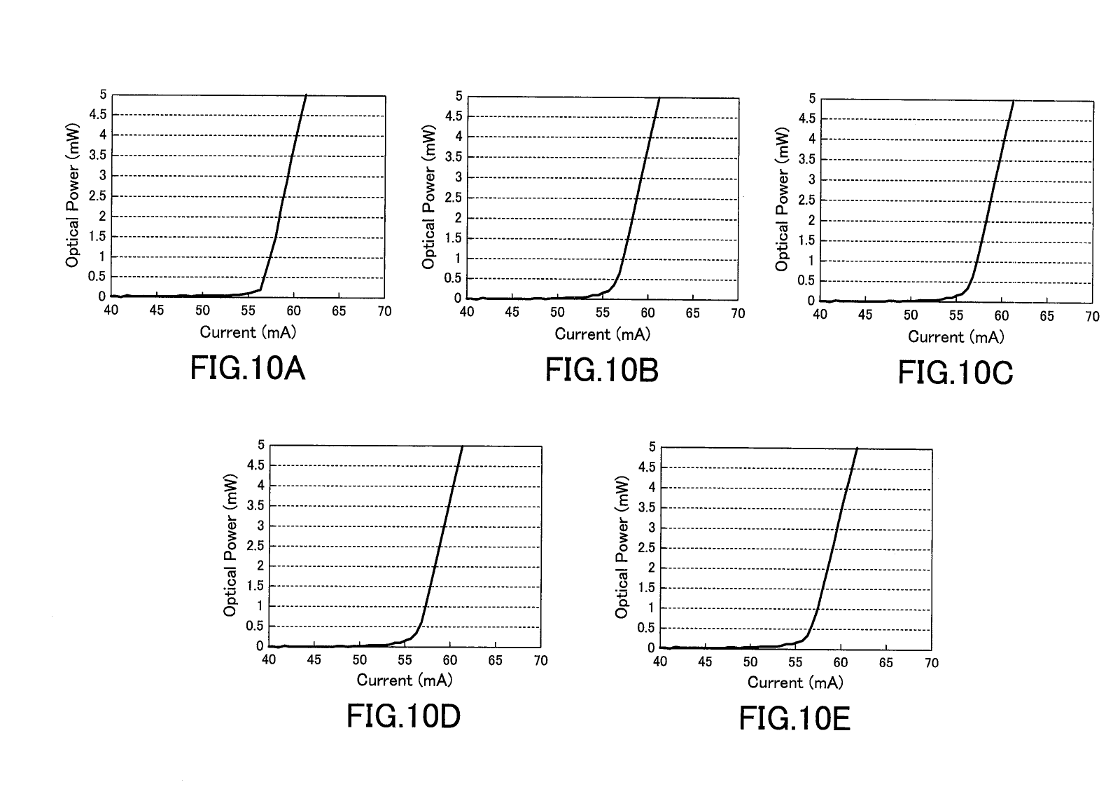

FIG. 10A shows the optical power-current characteristics of the example semiconductor laser device at 0° C. when the height of the ridge portion 20a is 1.0 μm. FIG. 10B shows the optical power-current characteristics at 0° C. when the height thereof is 1.3 μm. FIG. 10C shows the optical power-current characteristics at 0° C. when the height thereof is 1.6 μm. FIG. 10D shows the optical power-current characteristics at 0° C. when the height thereof is 1.9 μm. FIG. 10E shows the optical power-current characteristics at 0° C. when the height thereof is 2.2 μm.

As shown in FIG. 10A, when the height of the ridge portion 20a is 1.0 μm, the optical power-current characteristics show non-linearity. On the other hand, as shown in FIGS. 10B through 10E, when the height of the ridge portion 20a is 1.3 μm, 1.6 μm, 1.9 μm, or 2.2 μm, the optical power-current characteristics do not show non-linearity. More particularly, when the height of the ridge portion 20a is 1.3 μm or more, the absorption states in each transition region 32 are filled with carriers, and a part of the active layer 14 in the absorption states thus does not act as an absorber. This can provide optical power-current characteristics showing excellent linearity without showing non-linearity also in low-temperature operation at temperatures of 0° C. or less.

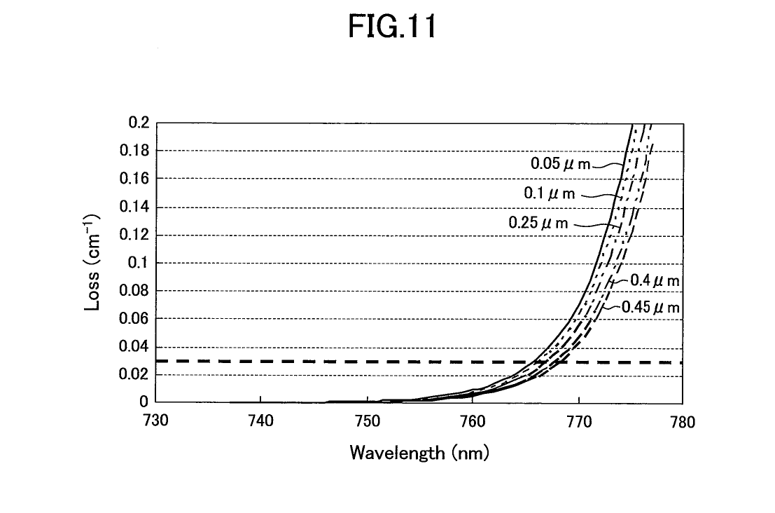

FIG. 11 shows the correlation between the wavelength of the absorption edge of each of parts of the active layer 14 located at the boundaries between the current injection portion 41 and the current non-injection portions 42 and the local mode loss of the associated transition region 32 when the thickness of the p-type cladding layer 16 is changed. In FIG. 11, calculations are performed on the assumption that the gain wavelength of the example semiconductor laser device is 777 nm and the temperature thereof is 0° C. The thickness of the p-type cladding layer 16 means the thickness of the portion of the p-type cladding layer 16 excluding the ridge portion 20a.

As shown in FIG. 11, with the increasing thickness of the p-type cladding layer 16, the local mode loss of the transition region 32 is reduced. An increase in the thickness of the p-type cladding layer 16 increases the spread of current toward the end face of the laser device. The spread of current may occur when current injected from the ridge portion 20a flows into the active layer 14. When the spread of current toward the end face is increased, current is injected into the tail states and the impurity states in the transition region 32. Consequently, these states are filled with carriers, and thus light absorption is reduced. Therefore, the local mode loss may be reduced.

When the thickness of the p-type cladding layer 16 is 0.4 μm or more, the effective refractive index difference Δn between the inner and outer sides of the ridge portion 20a is 1×10⁻³ or less. Therefore, a confinement mechanism for confining the light distribution horizontally changes from an index-guiding mechanism to a gain-guiding mechanism. As a result, the shape of the light distribution is more likely to be affected by the horizontal carrier distribution in the active layer 14. For this reason, the shape of the light distribution is more likely to vary according to the operating current value, leading to a reduced kink level. Consequently, kinks may appear at high powers, e.g., powers exceeding 250 mW. In view of the above, in order to achieve high power operation, the thickness of the p-type cladding layer 16 is preferably 0.4 μm or less.

On the other hand, when the difference Δn is 1×10⁻² or more, the light distribution is strongly laterally confined even with a narrow ridge width of 1.5 through 3 μm. This hinders a higher-order transverse mode from being cut off in high-temperature operation, leading to kinks in the optical power-current characteristics. When the thickness of the p-type cladding layer 16 is 0.05 μm or less, the difference Δn becomes 1×10⁻² or more. For this reason, in order to prevent oscillation in the higher-order transverse mode in high-temperature operation, the p-type cladding layer 16 preferably has a thickness of 0.05 μm or more.

In view of the above, in order to provide stable oscillation in a fundamental transverse mode by suppressing oscillation in the higher-order transverse mode in high-temperature operation and a variation in the shape of the light distribution according to variations in the operating current value, the thickness of the p-type cladding layer 16 is preferably in the range from 0.1 μm to 0.4 μm, both inclusive. In this case, the difference Δn is within the range from 1×10⁻³ to 7×10⁻³, both inclusive. In this example embodiment, in order that the difference Δn can be 5×10⁻³, the thickness of the p-type cladding layer 16 should be 0.15 μm.

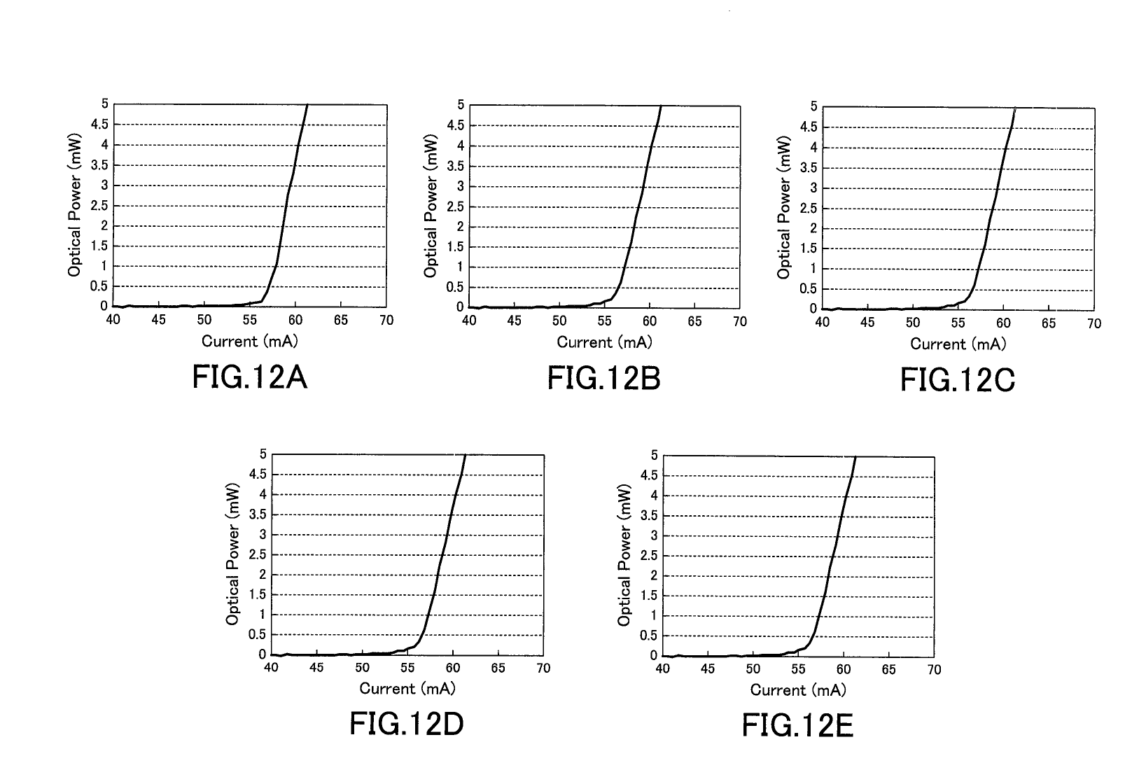

FIG. 12A shows the optical power-current characteristics of the example semiconductor laser device at 0° C. when the thickness of the p-type cladding layer 16 is 0.05 μm. FIG. 12B shows the optical power-current characteristics at 0° C. when the thickness thereof is 0.1 μm. FIG. 12C shows the optical power-current characteristics at 0° C. when the thickness thereof is 0.25 μm. FIG. 12D shows the optical power-current characteristics at 0° C. when the thickness thereof is 0.4 μm. FIG. 12E shows the optical power-current characteristics at 0° C. when the thickness thereof is 0.45 μm.

As shown in FIG. 12A, when the thickness of the p-type cladding layer 16 is 0.05 μm, the optical power-current characteristics show non-linearity. On the other hand, as shown in FIGS. 12B through 12E, when the thickness of the p-type cladding layer 16 is 0.1 μm or more, the optical power-current characteristics do not show non-linearity. More particularly, when the thickness of the p-type cladding layer 16 is 0.1 μm or more, the absorption states in the transition region 32 are filled with carriers, and a part of the active layer 14 in the absorption states thus does not act as an absorber. This can provide optical power-current characteristics showing excellent linearity without showing non-linearity also in low-temperature operation at temperatures of 0° C. or less.

As described above, the carrier concentration in the ridge portion 20a, the height of the ridge portion 20a, and the thickness of the p-type cladding layer 16 affects the linearity of the optical power-current characteristics in low-temperature operation. Therefore, when one of these conditions, a combination of two of these conditions, or all of these conditions are optimized, this optimization can improve the linearity of the optical power-current characteristics, in particular, in low-temperature operation. If the boundaries between the current injection portion 41 and the current non-injection portions 42 are located in the transition regions 32, this configuration can improve the linearity of the optical power-current characteristics. Moreover, if one of the carrier concentration in the ridge portion 20a, the height of the ridge portion 20a, and the thickness of the p-type cladding layer 16, a combination of two thereof, or all thereof are optimized, this optimization can further improve the linearity of the optical power-current characteristics.

More specifically, each of the boundaries between the current injection portion 41 and the current non-injection portions 42 are preferably located closer to the end face window regions 33 than the location at which the wavelength of the absorption edge of the associated transition region 32 is 11 nm shorter than that of the gain region 31. The carrier concentration in the ridge portion 20a is preferably greater than or equal to 5×10¹⁷ cm⁻³ and less than or equal to 2×10¹⁸ cm⁻³. The height of the ridge portion 20a is preferably greater than or equal to 1.3 μm and less than or equal to 1.9 μm. The thickness of the p-type cladding layer 16 is preferably greater than or equal to 0.1 μm and less than or equal to 0.4 μm.

When all of the carrier concentration in the ridge portion 20a, the height of the ridge portion 20a, and the thickness of the p-type cladding layer 16 are optimized, this optimization can maximally improve the linearity of the optical power-current characteristics. However, when one or two of these conditions are optimized, this optimization can also improve the linearity of the optical power-current characteristics.

When the configuration of the example semiconductor laser device is applied not only to an AlGaAs-based infrared semiconductor laser device but also to an AlGaInP-based red semiconductor laser device or the like, it can provide similar advantages.

As described above, the example semiconductor laser device can provide optical power-current characteristics showing excellent linearity also in low-temperature operation, and is useful, in particular, as a high-power semiconductor laser device for use in an optical disk drive or any other apparatus.

The description of the embodiment of the present invention is given above for the understanding of the present invention. It will be understood that the invention is not limited to the particular embodiment described herein, but is capable of various modifications, rearrangements and substitutions as will now become apparent to those skilled in the art without departing from the scope of the invention. Therefore, it is intended that the following claims cover all such modifications and changes as fall within the true spirit and scope of the invention.

What is claimed is:

1. A semiconductor laser device comprising
a semiconductor layer forming a resonator, and including a cladding layer of a first conductivity type, an active layer, and a cladding layer of a second conductivity type having a ridge portion, the cladding layer of the first conductivity type, the active layer, and the cladding layer of the second conductivity type being formed sequentially on a substrate,
wherein the active layer includes:
a gain region;
an end face window region formed in a region of the active layer including an end face of the resonator, and having a larger band gap energy than the gain region; and
a transition region formed between the gain region and the end face window region, a band gap energy of the transition region continuously changing from a band gap energy of the gain region to a band gap energy of the end face window region,
the gain region and a portion of the transition region located near the gain region form a current injection portion into which current is injected, and
the end face window region and a portion of the transition region located near the end face window region form a current non-injection portion into which current is prevented from being injected.

2. The device of claim 1, wherein
the boundary between the current injection portion and the current non-injection portion is located closer to the end face window region than the location at which the wavelength of the absorption edge of the transition region is approximately 11 nm shorter than that of the gain region.

3. The device of claim 1, wherein
a part of the ridge portion located on the gain region has an impurity carrier concentration greater than or equal to approximately 5×10¹⁷ cm⁻³ and less than or equal to approximately 2×10¹⁸ cm⁻³.

4. The device of claim 1, wherein
the height of the ridge portion is greater than or equal to approximately 1.3 μm and less than or equal to approximately 1.9 μm.

5. The device of claim 1, wherein
the thickness of a portion of the cladding layer of the second conductivity type excluding the ridge portion is greater than or equal to approximately 0.1 μm and less than or equal to approximately 0.4 μm.

6. The device of claim 1, wherein
the cladding layer of the first conductivity type and the cladding layer of the second conductivity type are AlGaInP-based semiconductor layers, and
the active layer is an AlGaAs-based semiconductor layer.
